(19) United States
(12) Patent Application Publication
(10) Pub. No.: US 2024/0288766 A1
(43) Pub. Date: Aug. 29, 2024

(54) INDIUM BASED SOL-GEL OXIDE PRECURSOR FILMS AS EXTREME ULTRAVIOLET AND LOW-ENERGY ELECTRON BEAM RESISTS

(71) Applicant: Board of Regents, The University of Texas System, Austin, TX (US)

(72) Inventors: Julia W.P. Hsu, Plano, TX (US); Trey B. Daunis, Plano, TX (US)

(73) Assignee: Board of Regents, The University of Texas System, Austin, TX (US)

(21) Appl. No.: 18/174,732

(22) Filed: Feb. 27, 2023

(51) Int. Cl. G03F 7/004; G03F 7/16

(52) U.S. Cl. CPC G03F 7/0043; G03F 7/162

(57) ABSTRACT

A method for lithography includes preparing an indium-based precursor solution. The precursor solution is not limited to indium and may include other metals such as, but not limited to, zinc, tin, aluminum, or gallium, in addition to indium. Additionally, the precursor solution may include a nitrate, an acetate, a chloride, an acetylacetonate, an iodide, and other organic or inorganic groups. The method further includes spin-coating the precursor solution on a substrate at a predetermined rate to form a resist film with a predetermined thickness. The method further includes exposing the resist film to one of a low-energy electron beam and an extreme ultraviolet (EUV) beam to produce one or more chemical changes on the resist film to form a pattern. The resist is negative tone with the exposed regions remaining on the substrate and unexposed regions being removed from the substrate by the developer.

### FIELD OF THE INVENTION

The disclosure describes preparing an indium-based sol-gel precursor film and performing lithography by using the precursor film as a negative lithographic resist.

### BACKGROUND OF THE INVENTION

Extreme ultraviolet (EUV) lithography is an advanced lithography technique that can produce 10-nanometer (nm) resolution while having a capability of high-volume manufacturing. EUV lithography uses photons of 13.5 nm wavelength (or 92 eV energy). Because of the high energy of the photons, the photon number density is much lower than the traditional deep ultraviolet (DUV) sources at the same dose (radiant energy density). Chemically amplified resists (CARs) have been the workhorse photoresist for DUV. When using CARs in EUV lithography, they suffer from lack of sensitivity because carbon has a low EUV absorption cross-section. The requirement of thin resists in EUV lithography further exacerbates the problem. Adding more photoacid generators in CARs has not solved the problems.

Inorganic resists, in particular metal oxides, which are not used in DUV lithography, have been studied as potential EUV resists because elements such as metals, semimetals, and transition metals have larger EUV absorption cross-sections than carbon. For instance, tin (Sn) has been targeted for preparing such resists because it has one of the highest cross-sections. The most advanced inorganic EUV resist is based on Sn-oxo compounds. The spherical Sn-oxo cages are made of tin-oxide cores surrounded by organic ligands and are a form of sol-gel precursors.

In lithography, resists are formed by spin-coating a precursor solution onto wafers to form thin films. During research on the Sn-oxo compound-based resists, Sn-oxo compounds were found to be a negative resist after their EUV exposure. Besides Sn, however, there has not been significant research on inorganic EUV resists containing other metal elements with high EUV absorption cross-sections.

The energy of EUV photons is 92 electron volts (eV). The absorption of EUV photons results in ionizing inner-shell electrons and the photoelectrons subsequently induce chemical changes that lead to a solubility switch. An electron beam (E-beam) with the same energy has also been used as a proxy for an EUV source because EUV lithography systems are extremely expensive. E-beam is also used to study the interaction between the resist and EUV-generated photoelectrons. The mechanisms for solubility switching when using charge-neutral EUV photons and negatively charged electrons can be different. Additionally, sample heating can happened during electron interaction with the resist but is absent in the EUV irradiation. Furthermore, at low electron energy (<1 keV), the solubility switch mechanism can be different from traditional electron beam lithography, which uses electrons with energies of a few to several hundred kilo electron volts (keV).

Therefore, there is a need to develop new resist materials for EUV lithography and low-energy electron beam lithography.

### SUMMARY OF THE INVENTION

A method for lithography addresses at least some of the above challenges and issues.

A method for lithography includes preparing an indium-based precursor solution. The precursor solution is not limited to indium and may include other metals such as, but not limited to, zinc, tin, aluminum, or gallium, in addition to indium. Additionally, the precursor solution may include a nitrate, an acetate, a chloride, an acetylacetonate, an iodide, and other organic or inorganic groups. The method further includes spin-coating the precursor solution on a substrate at a predetermined rate to form a resist film with a predetermined thickness. The method further includes exposing the resist film to one of a low-energy electron beam and an extreme ultraviolet (EUV) beam to produce one or more chemical changes on the resist film to form a pattern. The resist is negative tone with the exposed regions remaining on the substrate and unexposed regions being removed from the substrate by the developer.

A method of lithography includes preparing an indium-based precursor solution. The method further includes spin-coating the precursor solution on a substrate at a predetermined rate to form the EUV resist. The method further includes exposing the resist film to an EUV beam, using a mask or by direct writing, to produce one or more chemical changes on the resist film.

A method to prepare an EUV resist includes preparing an indium-based precursor solution. The method further includes spin-coating the precursor solution on a substrate at a predetermined rate to form a resist film.

### BRIEF DESCRIPTION OF THE DRAWINGS

Further advantages of the invention will become apparent by reference to the detailed description of preferred embodiments when considered in conjunction with the drawings:

FIG. 1A illustrates an optical microscope image showing macroscale defects of varied sizes on an indium nitrate hydrate resist film.

FIG. 1B illustrates a scanning electron microscopy (SEM) image of a macroscale defect for a resist film that is made at relative humidity (RH) of 23%.

FIGS. 2A-2C illustrate a comparison of macroscale defects observed on a 0.1M indium oxide (InOₓ), indium tin oxide (ITO), and indium zinc oxide (IZO) precursor films with all films made at an RH of 35%.

FIGS. 3A-3D illustrate examples of optical microscope images of indium nitrate hydrate resist films made from precursor solutions with a concentration of 0.1 M, 0.2 M, 0.3 M, and 0.4 M, respectively, with all films made at an RH of 26%.

FIG. 3E illustrates the effect of precursor concentration on macroscale defect density characterized with an optical microscope and a commercial software.

FIG. 4A illustrates the effect of RH on macroscale defect density of a 0.1 M indium nitrate hydrate resist film.

FIG. 4B illustrates the stability of macroscale defect density on a 0.1M indium nitrate hydrate resist film made at an RH of 39% over storage time.

FIG. 5 illustrates atomic force microscope (AFM) images and height profile of nanoscale bumps on a resist film made at an RH of 38%.

FIG. 6A illustrates the effect of RH on the volume density of these nanoscale bumps, according to an embodiment.

FIG. 6B illustrates a resist film made using the same precursor solution, at an RH of 40%, according to an embodiment.

FIG. 6C illustrates another resist film made using the same precursor solution, at an RH of 27%, according to an embodiment.

FIG. 7A illustrates outcomes of post-application bake (PAB) as a function of temperature and time.

FIG. 7B illustrates the effect of a PAB condition on macroscale defect density characterized with an optical microscope and a commercial software.

FIG. 7C illustrates the effect of PAB condition on nanoscale feature volume density (left axis) and the RMS roughness averaged from five 1×1 μm² areas (right axis) characterized with the AFM.

FIG. 7D illustrates the AFM images of an indium nitrate resist film made with a PAB condition of 80° C., 3 minutes (top) and a resist film made with PAB of 100° C., 1 minute (bottom).

FIG. 8A-8B illustrate thermogravimetric analysis (TGA) and differential scanning calorimetry (DSC) results for as-received indium nitrate hydrate from two different suppliers. Pictures of as-received materials are shown as insets.

FIG. 9A illustrates a comparison of macroscale defect density of resist films made at three RHs with indium nitrate hydrate dissolved for 1 hour (solid) versus overnight (hatched) in 2-methoxyethanol (2-MOE) before adding reagents.

FIG. 9B illustrates a comparison of nanoscale bump volume density and surface roughness of a resist film made using precursor solution with a 1-hour dissolution vs. overnight dissolution with both samples made at an RH of 40% PAB.

FIG. 10A illustrates Fourier transform infrared (FTIR) decomposition results of NH₃, H₂O, NO₃, and NO₂ for an electron beam (E-beam) exposed indium nitrate hydrate resist film made with the PAB condition of 80° C. for 3 minutes.

FIG. 10B illustrates partial pressure vs. mass-to-charge ratio (m/z) collected by the residual gas analyzer (RGA).

FIG. 10C illustrates an RGA loss of NO (m/z=30) vs. exposure time showing a total integrated partial pressure of 2.3×10⁻⁸ (Torr*min) with a time evolution of NO release.

FIGS. 10D-E illustrate optical images showing visual changes of before and after developing, respectively.

FIG. 11 illustrates a flowchart indicating a method of lithography.

### DETAILED DESCRIPTION

The following detailed description is presented to enable a person of ordinary skill in the art to make and use the invention. For purposes of explanation, specific details are set forth to provide a thorough understanding of the present invention. It will be apparent to one skilled in the art, however, that these specific details are not required to practice the invention. Descriptions of specific applications are provided only as representative examples. Various modifications to the preferred embodiments will be readily apparent to one skilled in the art, and the general principles defined herein may be applied to other embodiments and applications without departing from the scope of the invention. The present invention is not intended to be limited to the embodiments shown but is to be accorded the widest possible scope consistent with the principles and features disclosed herein.

An EUV resist prepared from indium nitrate hydrate (In(NO₃)₃·x(H₂O)) will now be described. Indium nitrate hydrate is chosen for the EUV resist preparation because of a high EUV absorption cross-section of indium, low thermal decomposition temperatures of metal nitrates, and the adaptation of combustion sol-gel synthesis. The EUV absorption cross-section for indium is comparable to that of tin and therefore, it is expected to be sensitive to EUV exposure. The lower thermal decomposition temperatures of metal nitrates indicate that less energy is required to convert the salt to indium oxide compared to other sol-gel precursors. Additionally, unlike Sn-oxo compounds, indium nitrate hydrate precursor does not include carbon.

The inventors tested the solubility switch of indium nitrate hydrate films under a 92-eV E-beam exposure. A likely mechanism for the conversion of indium nitrate hydrate to indium oxide begins by releasing water that was bonded to the salt, followed by the decomposition of the nitrates to nitric acid. As the reaction proceeds NO/NO₂ and oxygen are released, and indium hydroxide is formed. Condensation and densification are the last two stages of the conversion as indium hydroxide converts to indium oxide. The thermal decomposition temperature can be further lowered by using a combustion sol-gel formulation, which includes a fuel and an oxidizer. The fuel raises the energy content of the reactants, hence, requiring less external energy to overcome the barrier for the exothermic reaction.

The following embodiments describe a method for lithography. In an embodiment, the method includes preparing a lithographic resist film having a thickness of 20 nm and subsequently, exposing the resist film to the 92-eV E-beam or an EUV beam. The exposure of the resist film to the E-beam or the EUV beam results in chemical changes on the resist film. This method is described in more detail as follows.

### Precursor Synthesis

The indium nitrate precursor formulation including indium (III) nitrate hydrate (In(NO₃)₃·x(H20)) may be obtained from commercial suppliers, such as, but not limited to, Sigma-Aldrich or ThermoFisher. Most results in the embodiments described herein, were obtained using Sigma-Aldrich materials, unless otherwise specified. For instance, zinc nitrate hexahydrate (#96482) may be obtained from Sigma-Aldrich. Tin (II) chloride hydrate may be obtained from another commercial supplier such as, but not limited to, Alfa Aesar (#10894). Other reagents and solvents may be obtained from Sigma-Aldrich unless otherwise specified, and all above-mentioned ingredients may be used, as received.

The preparation of 0.1 M indium nitrate hydrate precursor solution begins by dissolving 141 mg of In (NO₃)₃·xH₂O in 4 mL of 2-methoxyethanol (2-MOE) solvent with continuous stirring, to form a solution. Once the metal salt is dissolved according to visual inspection, for a predetermined time duration (greater than or equal to 1 hour), 40 μL of acetylacetone and 27 μL of 14.5 M aqueous ammonia (NH₃) are added to the solution to form a combined solution. This combined solution is allowed to stir overnight (e.g., 12 hours) to form the 0.1M indium nitrate hydrate precursor solution.

An indium zinc oxide (IZO) precursor solution may alternately be prepared as the precursor solution. To make a 0.1 M IZO precursor solution, dissolution occurs by stirring 75.8 mg of Zn(NO₃)₂·6H₂O in 4 mL 2-MOE for 1 hour, and then adding 40 μL of acetylacetone and 27 μL of 14.5 M aqueous NH₃. The combined solution is allowed to stir overnight (e.g., 12 hours). The IZO precursor solution is formed by mixing the In- and Zn-containing solutions in a 7:3 ratio and letting it stir for an additional hour.

An indium tin oxide (ITO) precursor solution may be alternately prepared. For instance, to prepare a 0.1 ITO precursor solution, 75.8 mg of SnCl₂ with 32.02 mg of NH₄NO₃ are added into 4 mL of 2-MOE and stirred for 1 hour before adding 40 μL of acetylacetone and 13.5 μL of 14.5 M aqueous NH₃ and then letting it stir for 12 hours. The ITO precursor solution is formed by mixing the In- and Sn-containing solutions in 9:1 ratio and letting it stir for an additional hour. For higher-concentration precursor solutions, the amounts may be adjusted accordingly, and the same procedure may be followed.

In an embodiment, the precursor solutions may be filtered with a 0.22 μm polytetrafluoroethylene (PTFE) filter immediately before their further usage.

### Spin-Coating Procedure

The indium nitrate hydrate precursor solution is subsequently spin-coated onto polished silicon wafer pieces as a substrate (or substrates), at a rate of 3,500 rpm for 35 seconds. The silicon wafer substrate may be cut into multiple wafer pieces with the dimension of each piece being 1.5×3.8 cm². However, the dimensions of the wafer pieces are not limited to the aforementioned dimensions and may range from 1×1 centimeter² (cm²) to larger than 28.3 inches² (6-in wafers).

In an alternate experimental embodiment, the IZO and ITO precursor solutions may be spin-coated onto the same substrates but at a rate of 3,500 rpm and 2,000 rpm, respectively for 35 seconds. The duration of 35 seconds may be predetermined based on the conditions of a laboratory, relative humidity for instance. Further, unless explicitly specified otherwise, all films may be treated with a PAB condition of 80° C. for 3 minutes, immediately following spin-coating.

### Characterization Methods

The spin-coated resist films may be studied using a commercial optical microscope, such as, but not limited to, Leica DM2500 M optical microscope equipped with a DFC450 microscope camera. For a quantitative analysis of the film quality, a defect density in units of #/mm² may be calculated by processing images captured from the camera with a suitable software such as, but not limited to, ImageJ, which is a Java-based software developed by the National Institute of Health in part with the Laboratory for Optical and Computational Instrumentation. Film roughness and nanoscale defects may be studied using an atomic force microscope (AFM, Asylum Research MFP-3D) operating in tapping mode.

To evaluate whether the precursor has been converted to oxides after E-beam or EUV exposure, the coated sample may be submerged into a weak-acid developer solution composed of a 15:5:1 ratio of methanol, water, and acetic acid for a predetermined time duration ranging from 15 seconds to 1 minute. The developer solution may remove any unconverted resist films entirely from the substrate. However, converted films that have undergone a solubility switch may no longer be removed by the developer. A pattern may thus be developed in the exposed regions of the resist film.

The amount of water in the indium nitrate hydrate starting materials may be characterized using thermogravimetric analysis (TGA) and differential scanning calorimetry (DSC) (Q600, TA Instruments) with a heating rate of 10° C. per minute from room temperature to 500° C. The experiments described herein may be conducted in air using as-received indium nitrate hydrate materials. A scanning electron microscopy (SEM) image may be taken by a Zeiss Sigma 500VP SEM. The accelerating voltage may be 3 kilovolt (kV), in an embodiment.

### E-Beam Exposure Description

The spin-coated resist film may then be exposed to an EUV beam or a low-energy (<1 keV) E-beam. In one example, the E-beam may be a low energy E-beam (<1 keV) such as, but not limited to, a 92-eV E-beam. A suitable commercial electron gun (for instance, Kimbell physics, EGA-1012) may be hosted in an ultrahigh vacuum (UHV) chamber with a pressure of approximately 10⁻⁹ Torr and can produce the E-beam with energy varying from 1-1000 eV. In one example, the E-beam may impinge on the sample perpendicularly.

During the E-beam exposure, chemical changes may be produced on the resist and may be monitored by infrared (IR) transmission measurement and the released gases may be identified using a residual gas analyzer (RGA). In an embodiment, the IR source and the MCT-B detector may be located outside of the chamber. The chamber has KBr windows for the IR beam to pass through. The sample is positioned at the Brewster angle with the IR beam. All IR spectra may be measured with a resolution of 4 cm⁻¹ and a spectral range of 400-4000 cm⁻¹. The RGA may be inserted from the top side of the UHV chamber. Additionally, the sample may be heated up to 1000 K through resistive heating, enabling a comparison of thermal vs. E-beam stimulated conversion.

The spin-coated wafer piece may be held onto the sample holder by two metal clips on both sides. The clips ensure the sample does not move during loading, unloading, and the E-beam exposure. A metal mask may be taped onto the wafer with copper tape to create exposed and unexposed regions on the resist film. For example, the metal mask may be superimposed on the substrate in such a manner that the substrate is exposed to the E-beam through the openings of the metal mask. The resist film may be exposed to the low-energy E-beam or the EUV beam either by using the metal mask or by direct writing on the resist film.

Further, the sample is placed into a load lock chamber and pumped down to the pressure of 10⁻⁹ Torr. Once the pressure is stable, the sample is transferred to the sample holder in the experimental chamber. The sample may be rotated to the Brewster angle for the FTIR measurement and kept in place throughout the E-beam experiment. This ensures constant FTIR intensity.

The E-beam energy and dose may be calibrated using a Faraday cup. When calibrating the energy, a cover on the faraday cup may be biased using a power supply and the corresponding current may be measured using an ammeter. As the voltage of the Faraday cup is increased to the E-beam voltage, the electrons are repelled and the current decreases abruptly. The E-beam energy is the value of the voltage at the intercept between the linear extrapolation of current density and the background. The dose may be determined from the Faraday cup current density for a given energy and emission current of the E-beam.

### Resist Characterization

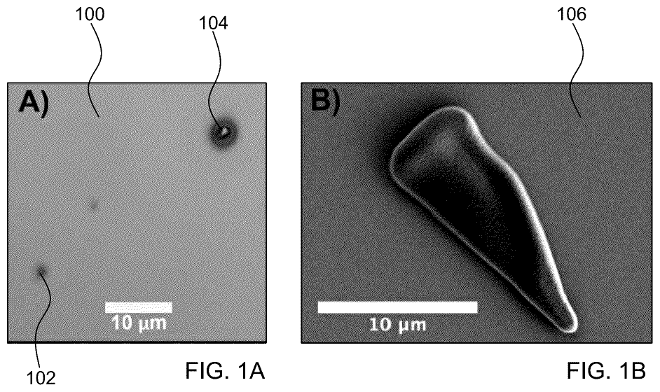

There are two kinds of defects on the indium nitrate hydrate resist films: macroscale defects that are visible under an optical microscope and nanoscale bumps that can only be seen using an atomic force microscope (AFM). An ideal resist film should be uniform and contain as few defects as possible. FIG. 1A illustrates an optical microscope image 100 showing macroscale defects of different sizes on a 0.1 M indium nitrate hydrate resist film, in an embodiment. The indium nitrate hydrate resist films exhibit small circular defects 102 visible under the optical microscope. The defects 102 include a nonhomogeneous feature surrounded by a halo 104 that has a different optical contrast, possibly due to different thicknesses.

When viewed at higher magnification in an SEM image 106, the crystalline structure becomes more apparent, as illustrated in FIG. 1B. These are likely indium nitrate hydrate crystals arising from incomplete dissolution. Most results in this observation may be based on a 1-hour indium nitrate hydrate dissolution time, unless otherwise specified.

The following embodiments of this disclosure describe these macroscale defects as a function of humidity, precursor concentration, metal elements, and PAB conditions.

Adding other metal cations may minimize crystallization in resist films when exposed to air, moisture, or even just over an extended period. In particular, the addition of zinc or tin to make ITO or IZO is well-known, and both have myriad applications as transparent conducting oxide thin films.

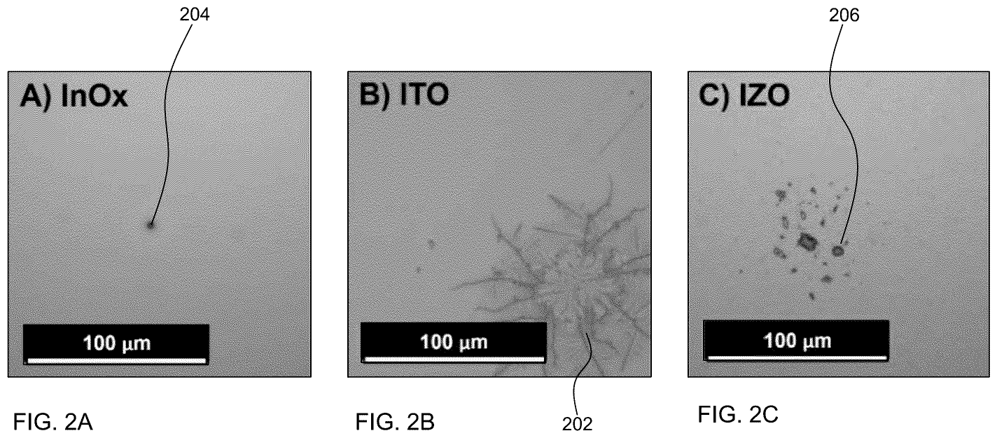

FIGS. 2A-2C illustrate a comparison of macroscale defects observed on 0.1 M indium oxide (InOₓ), indium tin oxide (ITO), and indium zinc oxide (IZO) precursor films with all films made at an RH of 35% and processed at PAB conditions of 80° C. for 3 min. As illustrated in FIG. 2B, ITO films developed large, dendritic crystals 202, which were not seen in other films within the timeframe of the experiment. Unlike the indium nitrate hydrate resist films that show circular dot defects 204 illustrated in FIG. 2A, IZO films exhibit irregularly shaped zinc-rich clusters 206, as illustrated in FIG. 2C. Overall, the indium oxide precursor film made from indium nitrate precursor solution are the most uniform among all three illustrated films.

The following description describes the effects of concentration dependence on the resist films. It is well known from solution chemistry and sol-gel science that the concentration can drastically impact the stability of a solution as well as the physical properties of a film after deposition. As the ratio between solute and solvent increases, the potential for solute materials to aggregate increases. Higher concentration solutions typically have poor solution dispersion, poor stability, and suffer agglomeration of solutes. These concentration effects may carry into the formation of the thin film after deposition.

In this experimental study, the molarity of indium nitrate hydrate sol-gel precursor solution was varied between 0.1 to 0.4 M to ascertain the optimal concentration for film formation. Each of the four concentrations was prepared following the precursor synthesis procedure described earlier in this disclosure. An exemplary method of evaluating the film qualitatively is by visual inspection and analysis under an optical microscope of the macroscale defects.

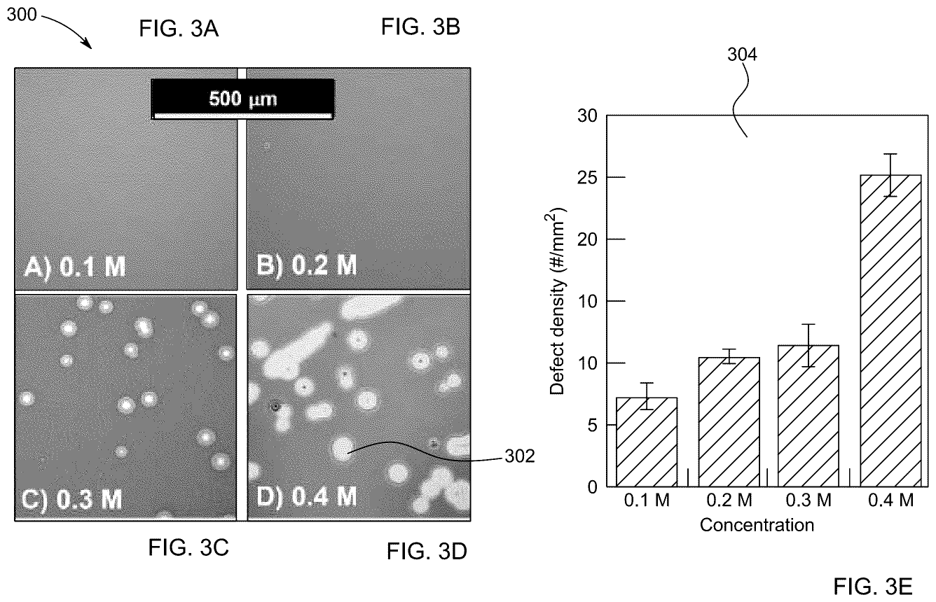

FIGS. 3A-3D illustrate examples of optical microscope images from 0.1 M, 0.2 M, 0.3 M, and 0.4 M indium nitrate hydrate resist films, respectively, with all films made at an RH of 26%. As the concentration increases, the defects begin to cover a larger portion of the film. The small dots (i.e., defects 102) on 0.1 M films in FIG. 1A develop large circular void regions 302 around them when the concentration is increased to 0.3 M and 0.4 M, as illustrated in FIGS. 3C and 3D.

A comparison of defect density for films made with different concentration precursors, as illustrated in a concentration chart 304 in FIG. 3E, reveals that high-concentration films have greater defect densities than low-concentration films. Ideal photoresists should have little to no defects and therefore, the indium nitrate hydrate sol-gel precursor should be 0.2 M or below.

The following embodiments describe the effect of humidity and time dependence on the resist films. Humidity is well known to affect sol-gel film formation, especially for hydrous metal oxides during the precursor solution and drying stages. In an industrial fabrication process, environmental conditions such as temperature and humidity are rigorously regulated. However, in an academic research laboratory, the ambient environment may not be controlled. Winter days typically may have a low relative humidity (RH) while summer days may have a high RH value. In an experimental study, research on indium nitrate hydrate film formation and stability was subject to drastically varying RH depending on the weather and the time of the year. The macroscale defect density was determined by counting the number of defects, as described earlier, from an optical microscope image using ImageJ and then dividing by the area of the image.

The humidity value may be taken from, for instance, a VWR Traceable digital humidity temperature/dew point meter (#89500-398) placed inside the fume hood where the indium nitrate hydrate resist films are spin-coated.

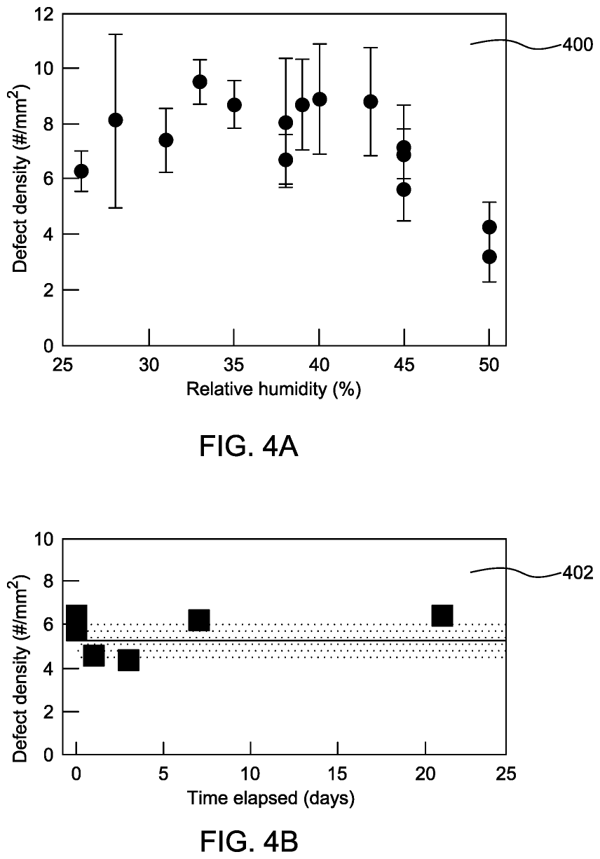

FIG. 4A illustrates the effect of RH on macroscale defect density of a 0.1 M indium nitrate hydrate resist film. For instance, a year-long investigation of film defect density as a function of RH varying from 26-50% is illustrated in a graph 400, in FIG. 4A. At low (<29%) and high (>46%) RH, the films have a lower defect density but contain other non-uniformities. When the humidity is low, the films may be impacted by the formation of dendritic crystals over time. When the humidity is high, the resist films develop the nanoscale features, as described later.

Over the moderate humidity level range from 30 to 45% RH, the macrosale defect density may be approximately independent of relative humidity. In the semiconductor manufacturing industry, a common RH range is (45±5)%. Thus, the above-described experimental study covered the working conditions the indium nitrate hydrate photoresist may likely be exposed to in an industrial setting. Some embodiments described below illustrate that the defect density depends on dissolution time and may be further decreased at a given humidity.

Another important factor to consider is how these defect features change over time. Ideally, the time between photoresist application, PAB, and EUV exposure should be kept as short as possible. However, a resist film should still exhibit excellent stability over the total processing time. This requires the resist film not to develop new defects over time.

During an experimental study, to determine the stability of indium nitrate hydrate resist films, the defect density of a 0.1 M indium nitrate hydrate resist film made at RH=39% was monitored for an extended period using an optical microscope. A graph 402 illustrated in FIG. 4B shows that even after a time duration of 20 days, the film manifested no crystallization or change in defect density. Other films were monitored for shorter times but also showed no new defects. The fact that these films were kept in an ambient environment and faced variation in humidity after the initial application step demonstrates the stability of indium nitrate hydrate resist films.

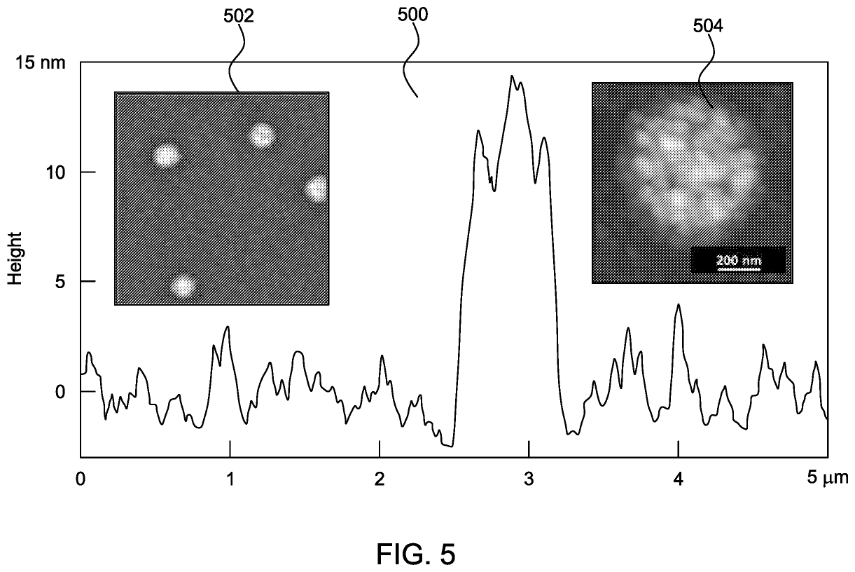

FIG. 5 illustrates an AFM topographic trace over one nanoscale bump on a 0.1 M indium nitrate hydrate resist film made at an RH of 38% along with AFM images of nanoscale bumps. The main plot 500 shows a line profile of an individual bump. The left inset image 502 shows an AFM image of an area that contains several bumps. The right inset 504 shows a zoomed-in image of a bump with details.

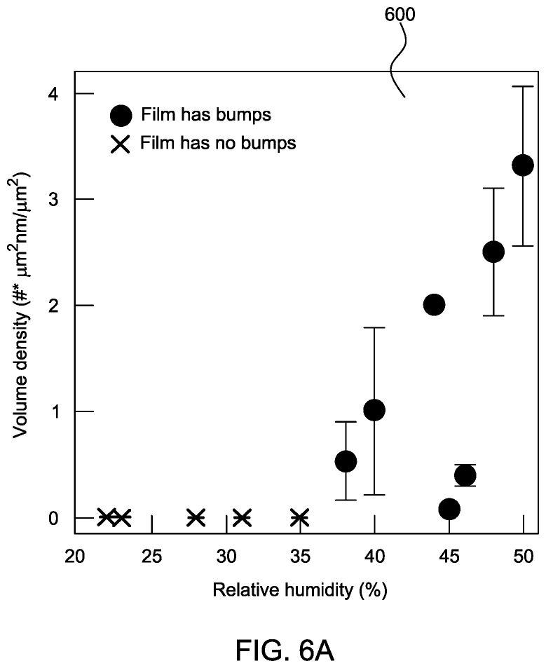

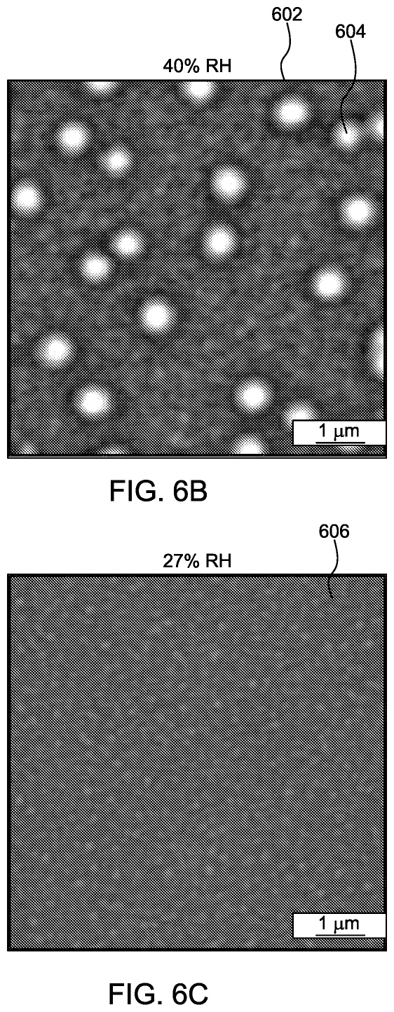

FIG. 6A illustrates a plot 600 showing the effect of RH on the volume density of these nanoscale bumps. Data points marked with an ‘x’ indicate humidity levels at which no bumps were observed on the film. Specifically, the bump volume density as a function of RH from 20% to 50% is illustrated, which displays an overall positive trend.

FIG. 6B illustrates a sample 602 made using the same precursor solution, at an RH of 40%, according to an embodiment. The sample 602 includes bumps 604. Since these bumps only appear at high humidity (bumps 604 indicated as circles in FIG. 6A 600) and their volume density increases with RH, it may be concluded that the moisture in the air induces the agglomeration of indium nitrate hydrate crystals in the sol-gel precursor solution or during the spin coating process.

To support this hypothesis, during an experimental study, a resist film was made in the morning when the RH was 40% and the nanoscale bumps were observed. Then later, the same day when the RH had dropped to 27%, another resist film was made using the same precursor solution, spin-coating procedure, and PAB conditions. It was observed that the resist film had no bumps, as illustrated in FIG. 6C. FIG. 6C illustrates another sample 606 made using the same precursor solution, at an RH of 27%, according to an embodiment.

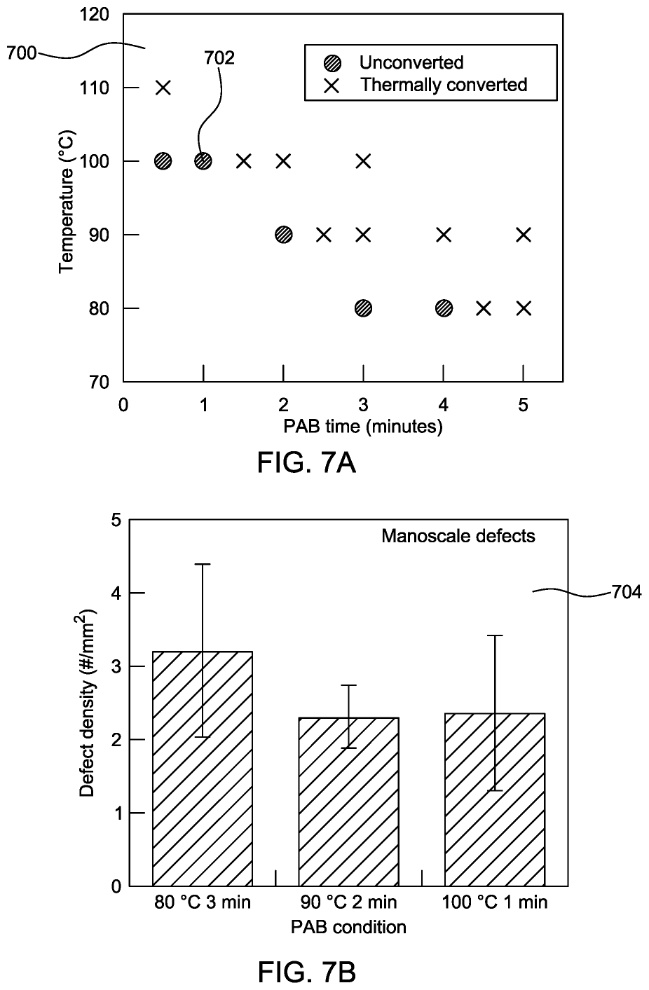

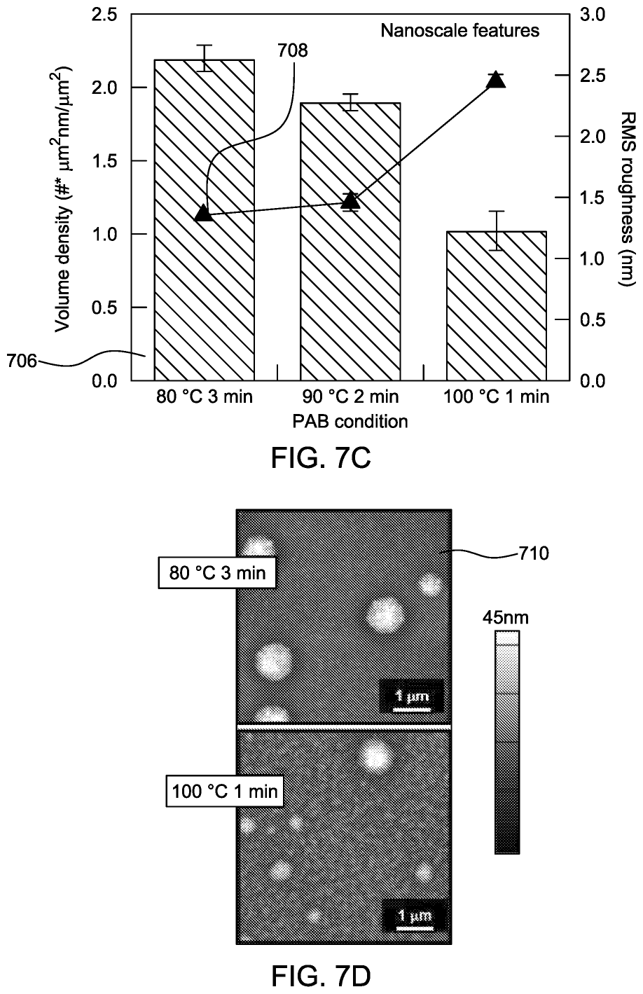

FIG. 7A illustrates an outcome plot 700 to show outcomes of PAB as a function of temperature and time. PAB may be an important photolithography step. After spin-coating, the applied film is heated at a low temperature to remove excess solvent, stabilize the film, and enhance the sensitivity to exposure. The PAB must be optimized with respect to both time and temperature. A resist that undergoes a PAB condition too low in temperature or too short in time would require an excess exposure dose or continue to change before exposure. A bake that is too high in temperature or too long in time could result in thermal conversion of the entire resist, rendering patterning in the exposure step ineffective.

The procedure in the experiments described above employed a PAB condition of 80° C. for 3 minutes immediately following spin-coating. Taking 80° C. as a starting point, higher temperatures were tested to evaporate more 2-MOE. Increasing temperature also means supplying the pre-exposed resist with more thermal energy that might lower the exposure dose required to induce chemical changes. The easiest method of testing other PAB conditions was to vary the PAB time at a given temperature until the resist film could no longer be removed by the developer, i.e., it was thermally converted. FIG. 7A shows all the explored PAB conditions and resultant outcomes. The circles 702 indicate that the film can still be removed by the developer and can be used for electron-beam or EUV exposure studies and crosses indicate the resist film is already thermally converted and cannot be used as a resist. From the plot, it is evident that the bake time must be reduced at higher temperatures.

PAB conditions of 90° C. for 2 minutes and 100° C. for 1 minute were chosen for further characterization to compare with the previous PAB conditions of 80° C. and 3 minutes. The film thickness may be lower when made at higher PAB temperatures, reducing from 31 nm for 80° C. 3 minutes to 22 nm for 100° C. 1 min, in one embodiment.

Further, the comparison of macroscale defect density and volume density of nanoscale defects for the three PAB conditions is illustrated in chart 704 shown in FIG. 7B and chart 706 shown in FIG. 7C, respectively. FIG. 7B illustrates similar macroscale defect density for the three PAB conditions. FIG. 7C shows nanoscale bump volume densities are similar for 80° C., 3 minutes and 90° C., 2 minutes and much lower for 100° C., 1 minute. This may create an assumption that a PAB of 100° C. for 1 minute would be better than lower temperatures. However, the 100° C. PAB film has a much higher RMS roughness (i.e., triangles 708, right axis illustrated in FIG. 7C).

FIG. 7D illustrates the AFM images 710 of a resist film made with a PAB condition of 80° C., 3 minutes (top) and a resist film made with PAB of 100° C., 1 minute (bottom). All films are made at an RH of 44%.

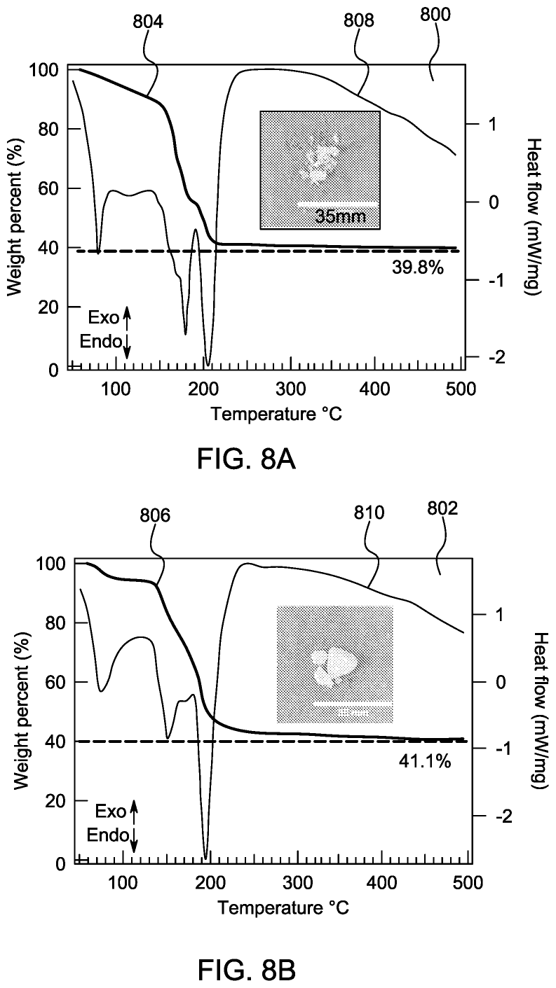

The following description describes the effect of different commercial chemical suppliers on the resist films. In one exemplary scenario, the indium nitrate hydrate may be sourced from two different suppliers. For instance, for the above-described experiments, indium nitrate hydrate was sourced from suppliers such as, but not limited to, Sigma-Aldrich and ThermoFisher Scientific. The indium salts from the two vendors were observed to have different appearances (FIGS. 8A-B): the Sigma-Aldrich indium nitrate hydrate materials are small semi-translucent crystals and dissolve quickly in 2-MOE, while the ThermoFisher materials are large opaque chunks and take much longer to dissolve. The following description characterizes their differences beyond appearance.

During an experimental study, the precursor solution was prepared from the ThermoFisher indium nitrate hydrate, as described earlier in this disclosure, but with a lengthened precursor dissolution time from 1 hour to 4-6 hours, to ensure the salt was properly dissolved. The indium nitrate hydrate materials were compared from the two vendors based on film defects while keeping humidity and PAB conditions the same.

TGA shows 39.8% of the mass left at high temperatures for the Sigma-Aldrich material, as illustrated in a graph 800 in FIG. 8A and 41.1% mass left for the ThermoFisher material, as illustrated in another graph 802 in FIG. 8B. The weight percentages of the starting materials that remained at high temperatures are indicated in the graphs. The curves 804 and 806 represent the TGA results in the respective figures. The curves 808 and 810 represent the DSC results in the respective figures.

Assuming only inorganic materials remain at high temperatures, the leftover mass may be indium oxide, In₂O₃. Thus, the water content may be calculated in the indium nitrate hydrate: x_{Sigma-Aldrich}=2.7 and x_{ThermoFisher}=2.0. Using the weight loss from room temperature to 150° C. and assuming it is entirely due to the loss of water in the indium nitrate hydrate, x_{Sigma-Aldrich}=2.3 and x_{ThermoFisher}=1.3, can be obtained. Thus, it can be concluded that the Sigma-Aldrich indium nitrate hydrate includes more water. The lower water content of ThermoFisher material therefore requires more time to properly dissolve.

For the DSC, the endothermic peaks are 79, 180, and 206° C. for the Sigma-Aldrich material and 74, 150, and 195° C. for the ThermoFisher materials. The peaks at 74-79° C. may be attributed to the evaporation of water. The 150-180° C. peak can be identified with the loss of HNO₃ and 195-206° C. is the conversion of In—OH to indium oxide.

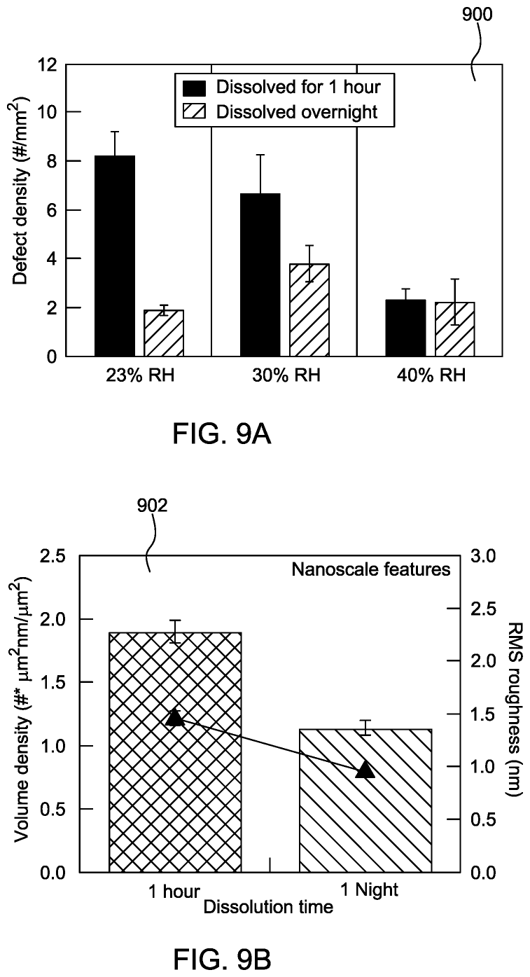

When preparing precursor solutions, a certain amount of time should be allowed for the solute to dissolve or the components to mix. As mentioned earlier, the defects observed on the resist films may be likely indium nitrate hydrate crystals arising from incomplete dissolution. To test this conjecture, a comparison may be made between the defects in films made from dissolving the indium nitrate salt in 2-MOE overnight instead of for only 1 hour. Precursor solutions prepared overnight produce films that are more uniform with fewer macroscale defects at low humidity, but the difference disappears at high humidity. At an RH of 23%, longer dissolution time results in a 4× lower macroscale defect density while both produce low defect density at RH=40%, as illustrated in a defect density graph 900, shown in FIG. 9A.

However, despite not observing an impact on the macroscale defects at 40% RH, the AFM analysis reveals that the longer dissolution reduces the RMS roughness and volume density of nanoscale features, as illustrated in the volume density plot 902, in FIG. 9B. Overall, allowing the indium nitrate hydrate to dissolve for at least overnight improves film quality.

### E-Beam Exposure Results

The following embodiments describe the E-beam exposure results. In an embodiment, the indium nitrate hydrate resist film may be exposed to the 92-eV E-beam at an emission current of 0.6 mA through a mask to evaluate the differences between exposed and unexposed regions of the film.

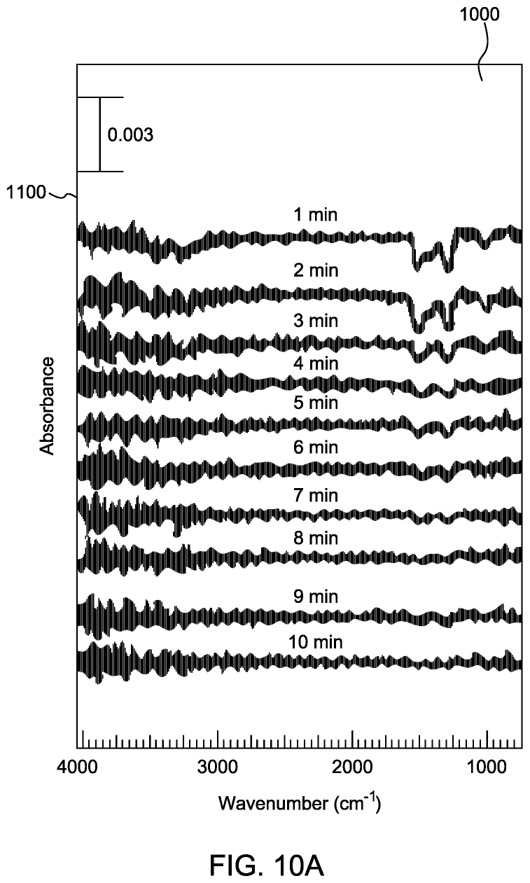

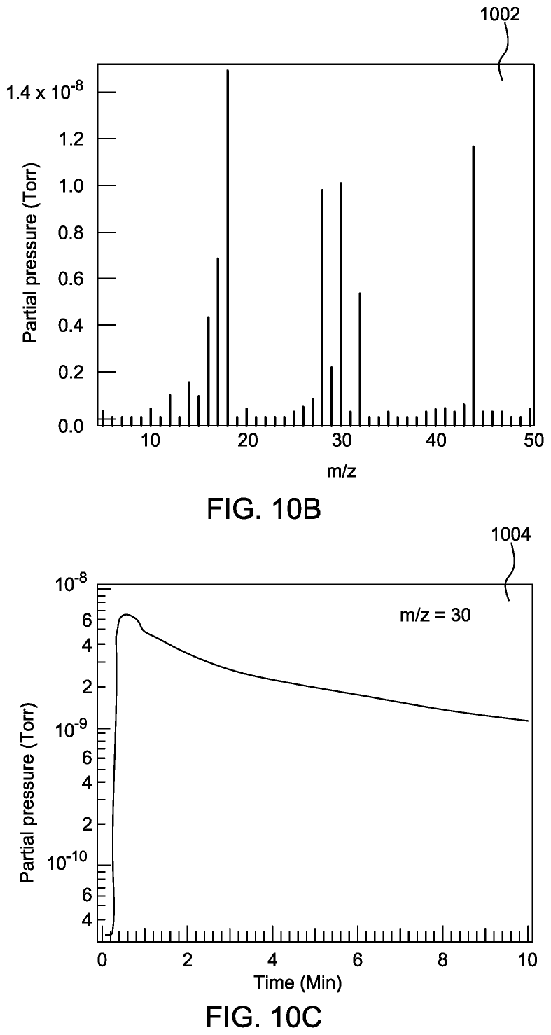

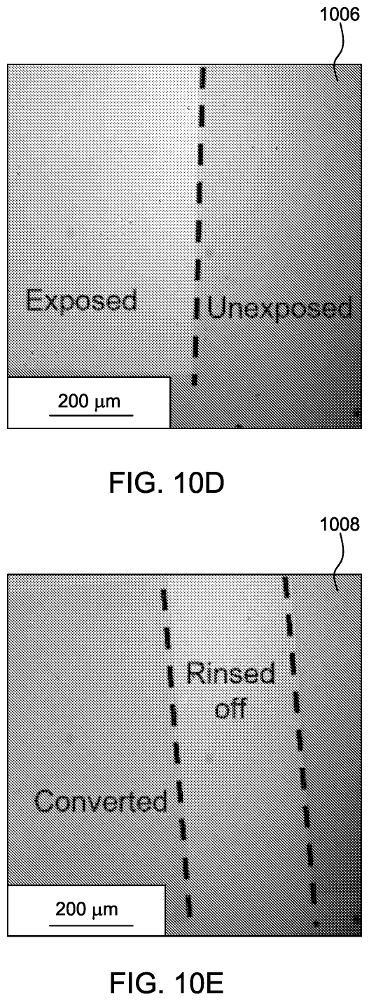

FIGS. 10A-E illustrate the results of a sample that has undergone E-beam exposure for 10 minutes, for a total exposure dose of 8.0 mC/cm². The PAB condition was 80° C. for 3 minutes. As illustrated by an absorbance chart 1000 in FIG. 10A, the time-sequence FTIR results illustrate a major loss of water (˜ 3500 cm⁻¹) and ammonia (˜ 3200 cm⁻¹) within the first two minutes of exposure. As the exposure continues, the loss of nitrate and nitrite shown by the N—O vibration mode (˜ 1550 to 1250 cm⁻¹) proceeded until 8 minutes of exposure. The identities of evolved gas molecules may be confirmed, using RGA simultaneously.

FIG. 10B illustrates a graph 1002 that indicates the gases released from the sample: H₂O (m/z=16, 17, 18, 19, 20), NH₃ (m/z=14, 15, 16, 17, 18), and NO (m/z=14, 15, 16, 30, 31, 32). A time evolution plot 1004 shown in FIG. 10C indicates a time evolution of NO release (m/z=30) with the integrated partial pressure calculated to be 2.3×10⁻⁸ Torr*minute.

FIG. 10D illustrates an optical image 1006 of the resist that has been exposed to E-beam while covered with a mask. After the exposure, the contrast between the exposed and unexposed regions was visible by the human eye and under an optical microscope, in the optical (microscopic) image illustrated in FIG. 10D.

FIG. 10E illustrates a developed resist using a developer solution such as a weak acid (15:5:1-MeOH:H₂O:CH₃COOH) showing contrast between the developed exposed portion and unexposed portion which is rinsed off. The solubility switch is demonstrated by developing the exposed sample in a weak acid, as illustrated by another microscopic image 1008, in FIG. 10E. The weak acid developer solution rinsed off the unexposed regions, while the exposed areas became insoluble and remained on the film. During an experimental study, E-beam exposure experiments were performed with indium nitrate hydrate samples processed with PAB conditions of 90° C. for 2 minutes and 100° C. for 1 minutes and similar results were observed.

The method may also subject the resist film to a post-exposure bake (PEB) condition having a predetermined temperature and a predetermined time duration to enhance the chemical change.

### CONCLUSION

The results encourage investigating the uniformity and stability of indium nitrate hydrate resist films as potential EUV resists. Varying precursor concentrations and mixed cations indicate that films made from 0.1 M pure indium nitrate hydrate solutions are the most uniform and stable over time in a standard laboratory environment. These films are 20-30 nm thick, as shown herein and suitable for EUV resist thickness. Quantitative analyses of optical microscopy and AFM images were performed to characterize defects at the macroscale and nanoscale, respectively. It is observed that the relative humidity and precursor dissolution time have a large effect on film morphology and defect density, but the PAB has a relatively smaller impact. In addition, it is observed that the precursor materials procured from different vendors have a different appearance and water content. They produce films with different morphology and nanoscale defects. The E-beam exposure experiment successfully triggers a solubility switch in these indium nitrate hydrate resist films.

Further, the indium nitrate hydrate films behave as a negative resist with exposed areas remained on the substrate and unexposed areas removed by the developer. In-situ FTIR shows loss water, ammonia, and nitrate/nitrate within the first 10 minutes of exposure, confirmed by RGA results. In summary, the method and results herein establish deposition and PAB conditions to fabricate uniform and stable indium nitrate hydrate resist films of desired thickness for EUV lithography and demonstrate their sensitivity to a solubility switch induced by 92-eV E-beam exposure.

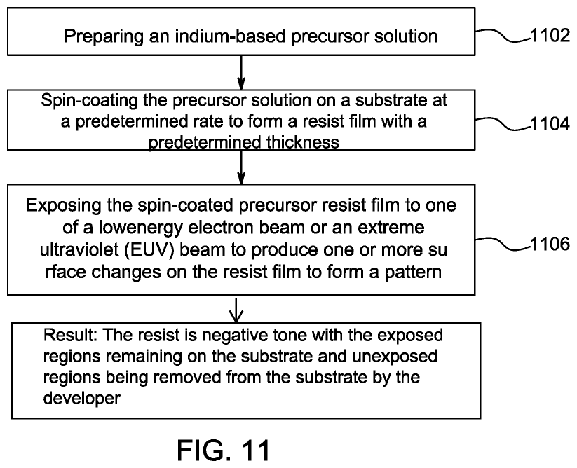

FIG. 11 illustrates a flowchart indicating a method of lithography. Step 1102 includes preparing an indium-based precursor solution, which may include other metals such as, but not limited to, zinc, tin, aluminum, and gallium. A person skilled in the art would understand that any other metal may be included in precursor solution and the embodiments are not limited to only the specified metals. Step 1104 includes spin-coating the precursor solution on a substrate at a predetermined rate to form a resist film of a predetermined thickness. Further, step 1106 includes exposing the spin-coated resist film to one of a low-energy electron beam or an extreme ultraviolet (EUV) beam to produce one or more chemical changes on the resist film to form a pattern. The resist is negative tone with the exposed regions remaining on the substrate and unexposed regions being removed from the substrate by the developer. A person skilled in the art would understand that the details of the above-described method have been described earlier in this disclosure and are not repeated for brevity.

One or more standard laboratory equipment and/or computer-readable storage media may be utilized in implementing embodiments consistent with the present disclosure. A person skilled in the art would understand that all laboratory equipment described in this disclosure may be connected to a local or a remote server unit for implantation of any processing tasks to implement the presented embodiments. Further, the computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., be non-transitory. Examples include random access memory (RAM), read-only memory (ROM), volatile memory, nonvolatile memory, hard drives, CD ROMs, DVDs, flash drives, disks, and any other known physical storage media.

The terms “comprising,” “including,” and “having,” as used in the claim and specification herein, shall be considered as indicating an open group that may include other elements not specified. The terms “a,” “an,” and the singular forms of words shall be taken to include the plural form of the same words, such that the terms mean that one or more of something is provided. The term “one” or “single” may be used to indicate that one and only one of something is intended. Similarly, other specific integer values, such as “two,” may be used when a specific number of things is intended. The terms “preferably,” “preferred,” “prefer,” “optionally,” “may,” and similar terms are used to indicate that an item, condition, or step being referred to is an optional (not required) feature of the invention.

The invention has been described with reference to various specific and preferred embodiments and techniques. However, it should be understood that many variations and modifications may be made while remaining within the spirit and scope of the invention. It will be apparent to one of ordinary skill in the art that methods, devices, device elements, materials, procedures, and techniques other than those specifically described herein can be applied to the practice of the invention as broadly disclosed herein without resort to undue experimentation. All art-known functional equivalents of methods, devices, device elements, materials, procedures, and techniques described herein are intended to be encompassed by this invention. Whenever a range is disclosed, all subranges and individual values are intended to be encompassed. This invention is not to be limited by the embodiments disclosed, including any shown in the drawings or exemplified in the specification, which are given by way of example and not of limitation. Additionally, it should be understood that the various embodiments of the networks, devices, and/or modules described herein contain optional features that can be individually or together applied to any other embodiment shown or contemplated here to be mixed and matched with the features of such networks, devices, and/or modules.

While the invention has been described with respect to a limited number of embodiments, those skilled in the art, having benefit of this disclosure, will appreciate that other embodiments can be devised which do not depart from the scope of the invention as disclosed herein.

I/We claim:

1. A method for lithography, the method comprising:
preparing an indium-based precursor solution;
spin-coating the precursor solution on a substrate at a predetermined rate to form a resist film; and
exposing the resist film to one of a low-energy electron beam and an extreme ultraviolet (EUV) beam to produce one or more chemical changes on the resist film.

2. The method of claim 1, wherein the precursor solution comprises an indium nitrate hydrate precursor solution.

3. The method of claim 1, wherein the precursor solution comprises other metals comprising one or more of zinc, tin, aluminum, or gallium, in addition to indium.

4. The method of claim 1, wherein the precursor solution comprises precursor materials comprising at least one of a nitrate, an acetate, a chloride, an acetylacetonate, an iodide, and other organic or inorganic groups.

5. The method of claim 1, wherein the low-energy electron beam comprises an electron beam with an energy of less than 1 kilo electron volt (keV).

6. The method of claim 1, wherein the resist film is formed to a predetermined thickness.

7. The method of claim 1, wherein the resist film is exposed to one of the low-energy electron beam and an extreme ultraviolet (EUV) beam by using a mask or by direct writing on the resist film.

8. The method of claim 1, wherein the substrate comprises one or more silicon wafers having a dimension ranging from 1×1 centimeter² (cm²) to larger than 28.3 inches² (6-in wafer).

9. The method of claim 1, wherein the EUV beam comprises an EUV photon having a 13.5 nm wavelength.

10. The method of claim 1, wherein the electron or EUV beam produces one or more chemical changes on an exposed region of the resist film.

11. The method of claim 1, further comprising developing a pattern in the exposed resist film by submerging the resist film in a developer solution.

12. The method of claim 11, wherein the developer solution comprises a composition of methanol, water, and acetic acid in a ratio of 15:5:1.

13. The method of claim 12, wherein the resist film is submerged for a time duration ranging from 15 seconds to 1 minute.

14. The method of claim 10, wherein the resist film comprises a negative resist with the exposed regions remaining on the substrate and unexposed regions being removed from the substrate by a developer.

15. The method of claim 1, further comprising baking the resist film under a post-application bake (PAB) condition having a predetermined temperature and a predetermined time duration.

16. The method of claim 10, further comprising baking the resist film under a post-exposure bake (PEB) condition having a predetermined temperature and a predetermined time duration to enhance the chemical change.

17. A method for lithography, the method comprising:
preparing an indium-based precursor solution;
spin-coating the precursor solution on a substrate at a predetermined rate to form an extreme ultraviolet (EUV) resist film; and
exposing the resist film to an EUV beam, using a mask or by direct writing, to produce one or more chemical changes on the resist film.

18. A method to prepare an extreme ultraviolet (EUV) resist, the method comprising:
preparing an indium-based precursor solution; and
spin-coating the precursor solution on a substrate at a predetermined rate to form a resist film.
